(19) United States
(12) Patent Application Publication
(10) Pub. No.: US 2008/0030939 A1
(43) Pub. Date: Feb. 7, 2008

(54) Mounting display

(75) Inventors: John Gillespie, Green Oaks, IL (US); Donald Lee Anderson, Oak Park, IL (US)

Correspondence Address: FOLEY & LARDNER LLP, 321 NORTH CLARK STREET, SUITE 2800, CHICAGO, IL, 60610-4764, US

(73) Assignee: Peerless Industries, Inc.

(21) Appl. No.: 11/888,749

(22) Filed: Aug. 2, 2007

Related U.S. Application Data
(60) Provisional application No. 60/835,994, filed on Aug. 7, 2006.

(51) Int. Cl. H05K 7/00

(52) U.S. Cl. 361/681

(57) ABSTRACT

A system for securing an electronic device to a surface. A display device is connected to an adaptor plate. The adaptor plate is engagable with an adaptor bracket positioned on a support column. The support column connects to a mounting assembly which is affixed to a surface. The mounting assembly is engagable with a floor and/or a ceiling to provide support for the display device from below or above, respectively.

### CROSS-REFERENCE TO RELATED APPLICATIONS

The present application claims priority to U.S. Provisional Patent Application No. 60/835,994, filed Aug. 7, 2006 and incorporated herein by reference in its entirety.

### FIELD OF THE INVENTION

The present invention relates generally to systems for mounting display devices such as flat panel televisions. More particularly, the present invention relates to systems for securing a mounting system's device adaptor bracket in position during an installation process. More specifically, the present invention relates to video displays mounted from a floor and/or ceiling.

### BACKGROUND OF THE INVENTION

The use of video displays outside of the family living room has become commonplace. However, current video display stands exhibit at least two problems. First, commercially available display stands are not versatile and tend to be very specialized. Commercially available display stands often are difficult to install and require professional installation. They provide little flexibility regarding the use of accessories such as television tuners or digital media players. In particular, commercially available display stands do not provide for a compact area of both the video display and accessories, nor do they provide an easy to use mechanism for adding such accessories to the display. Furthermore, commercially available stands typically are difficult to adjust or disassembly.

Second, most commercially available video display stands require a user to know how the video display stand will be mounted prior to selecting the type of display stand. This stems from the fact that commercially available video display stands require a specific type of mounting scenario, i.e. ceiling mounting or floor mounting. Thus, there is a need for a versatile and easy to use video display stand. In addition, there is also a need for a universally mounted video display stand.

### SUMMARY OF THE INVENTION

The present invention relates to display having an adaptor assembly engagable with a electronic device, a support column and a mounting assembly. One embodiment of the present invention comprises a floor mounted, pedestal-type display stand. Another embodiment of the present invention comprises a ceiling mounted, hanging-type display stand. Yet another embodiment of the present invention comprises a video display stand that is mountable either as a hanging-type display or a pedestal-type display.

These and other objects, advantages, and features of the invention, together with the organization and manner of operation thereof, will become apparent from the following detailed description when taken in conjunction with the accompanying drawings, wherein like elements have like numerals throughout the several drawings described below.

### BRIEF DESCRIPTION OF THE DRAWINGS

FIG. 1 is an exploded view of a mounting system according to a first embodiment of the present invention which is mounted to a ceiling;

FIG. 2 is an exploded view of a mounting system according to a second embodiment of the present invention which is mounted to a floor;

FIG. 3 is a perspective view of a ceiling mounting system of the present invention;

FIG. 4 is a perspective view of a floor mounting system of the present invention;

FIG. 5A is front view of a third embodiment of the present invention having a universal mounting assembly, where a display is mountable either from the ceiling or from the floor, with the components depending on how the display is mounted shown in phantom; FIG. 5B is a side view of the system of FIG. 5A; FIG. 5C is a perspective view from above of the system of FIG. 5A; and FIG. 5D is a perspective view from below of the system of FIG. 5A;

FIG. 6 is a perspective view of a mounting assembly of the ceiling mounting system of the present invention;

FIG. 7 is an overhead view of a mounting assembly of the ceiling mounting system of the present invention;

FIG. 8 is a perspective view of the ceiling mounting system of the present invention having turnbuckles;

FIG. 9 is a side-view of a support column and mounting assembly, prior to connection, of the ceiling mounting system;

FIG. 10 is a perspective view of connection of the support column and mounting assembly of FIG. 9;

FIG. 11A is a perspective view, prior to assembly, of an adaptor plate and adaptor bracket as mounted from the floor; and FIG. 11B is a perspective view, prior to assembly, of the adaptor assembly as mounted from the ceiling;

FIG. 12A is a perspective view of the adaptor assembly as mounted from the floor; and FIG. 12B is a perspective view of the adaptor assembly as mounted from the ceiling;

FIG. 13A is a perspective view, prior to assembly, of the video display and adaptor assembly as mounted from the floor; and FIG. 13B is a perspective view, prior to assembly, of the adaptor assembly as mounted from the ceiling;

FIG. 14A is a perspective view of a bottom speaker mount engagable with the adaptor assembly; and FIG. 14B is a perspective view of a top speaker mount engagable with the adaptor assembly;

FIG. 15 is a perspective view of a cover for engaging the adaptor assembly and video display;

FIG. 16 is a perspective view of a cavity for positioning of accessory items in the adaptor assembly; and

FIG. 17 is a perspective view of cutout portions in the adaptor assembly.

### DETAILED DESCRIPTION OF THE PREFERRED EMBODIMENTS

The present invention relates to a video display stand. In one aspect of the present invention, the display stand is mountable to a ceiling. In another aspect of the present invention, the display stand is mountable to a floor. In another aspect of the present invention, the display stand is mountable from either the floor and/or the ceiling.

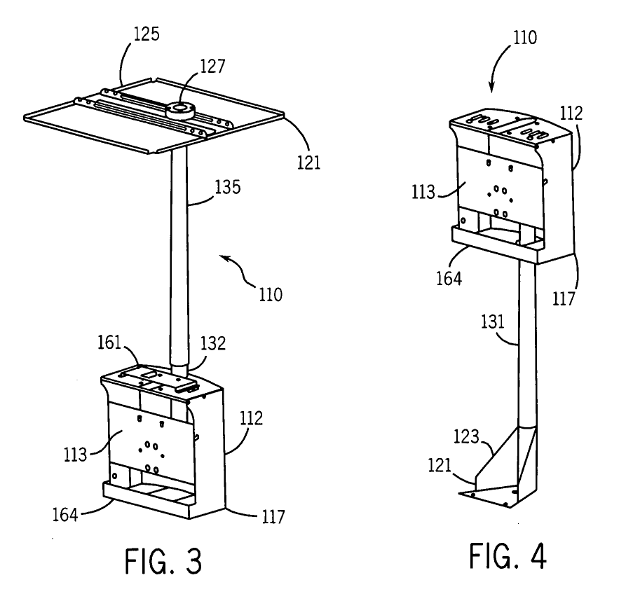

The present invention relates to a video display stand 110 which, as shown in FIGS. 3 and 4, comprises an adaptor assembly 112, a mounting assembly 121, and a support column 131. The adaptor assembly 112 is configured to receive a video display 111 and to be removably connected with the support column 131. The support column 131 is connected to the mounting assembly 121 which provides support for the display stand 110.

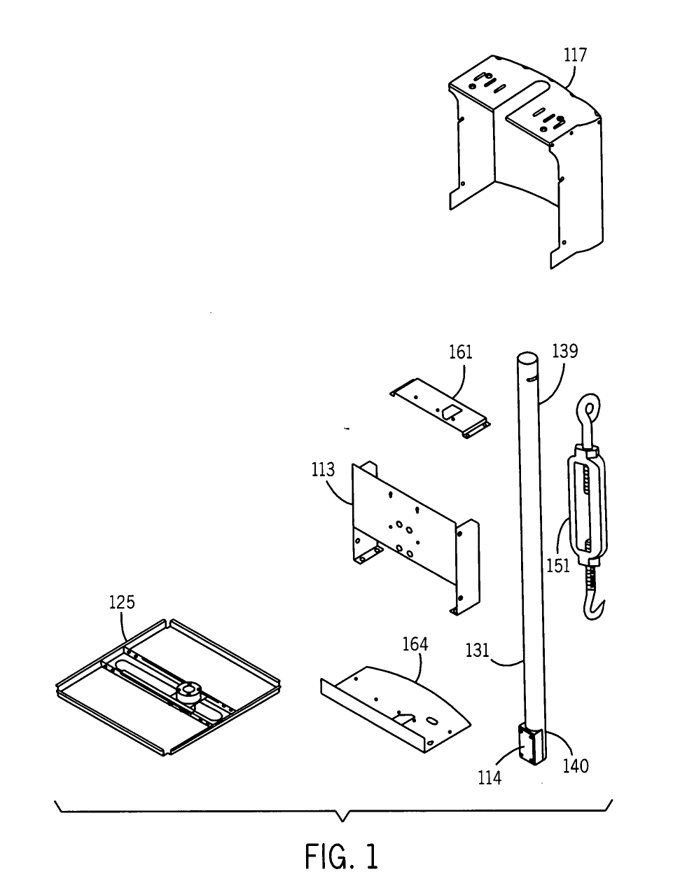

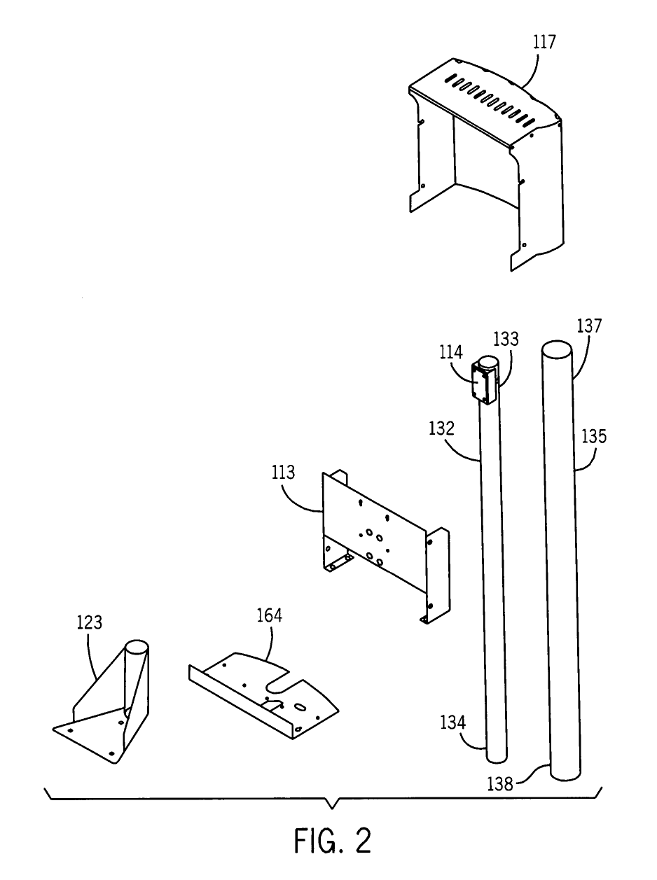

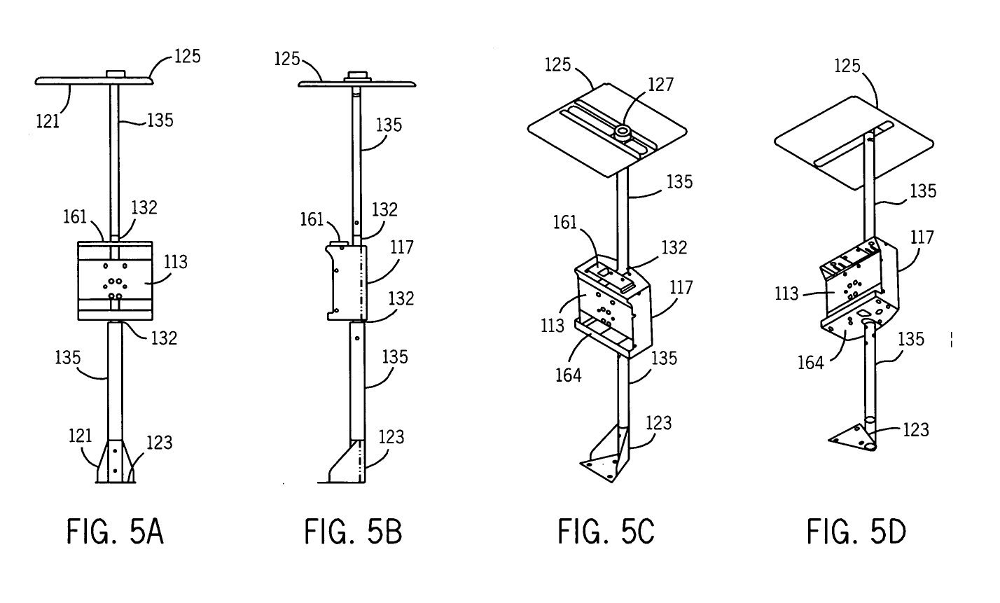

The support column 131 is engagable at a support column mounting end 139 with the mounting assembly 121. In a first embodiment, shown in FIGS. 1 (unassembled) and 3 (assembled), the mounting assembly 121 affixes to an overhead location wherein the video display stand 110 hangs from the overhead location. In a second embodiment, shown in FIGS. 2 (unassembled) and 4 (assembled), the mounting assembly 121 affixes to a ground location such that the video display stand 110 extends upward from the ground. In third embodiment, shown in FIG. 5, the support column 131 is affixable to either a ceiling mounted tray 125 or a floor mounted base 123.

In one embodiment, the video display stand 110 comprises a “pedestal-type” display stand, i.e. it is mountable to a floor. FIGS. 2 and 4 illustrate a video display stand 110 wherein the mounting assembly 121 comprises a base 123. The support column 131, which is affixable to a surface below the display 111, includes a support column mounting end 139 adapted to engage the base 123, with the mounting assembly 121 fixable to the support column 131. The base 123 is adapted to be securable to a floor or location below the video display stand 110 such that the mass of the video display stand 110 is support from below by the flooring or other lower surface.

In another embodiment, the video display stand 110 is a “hanging-type” display stand, i.e., it is mounted to an overhead support such as a ceiling. FIGS. 1 and 3 illustrate a video display stand 110 wherein the mounting assembly 121 includes a ceiling tray 125. The support column 131 having a mounting end 139 adapted to engage the ceiling tray 125 of the mounting assembly 121. The ceiling tray 125 is adapted to be securable to a ceiling or locations above the video display stand 110 such that the mass of the video display stand 110 is support from above.

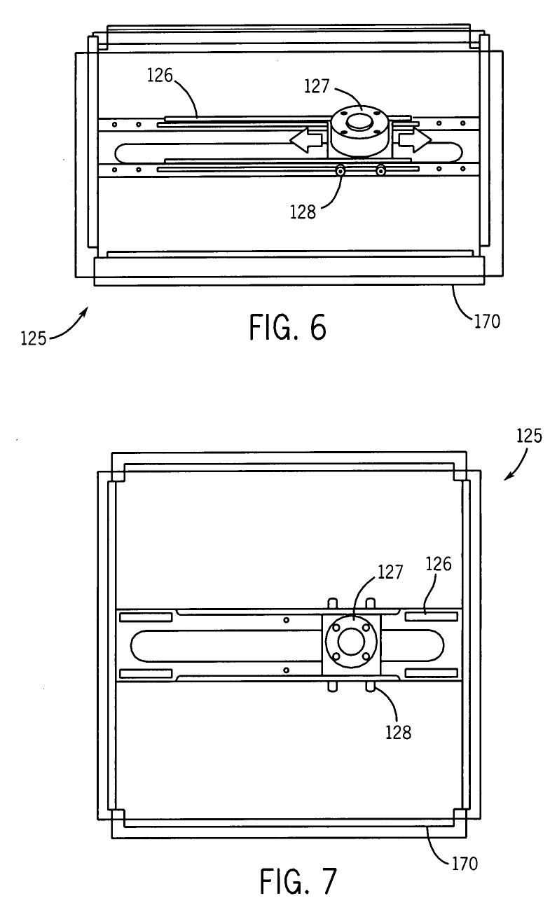

As illustrated in FIG. 6, the ceiling tray 125 may include a carriage 126 and a collar mount plate 127 which is slidably engagable with the carriage 126 or the ceiling tray 125, in one embodiment via one or more carriage bolts 128. The collar mount plate 127 is held in place in relation to the ceiling tray 125 such as by a carriage bolt 128.

As shown in FIGS. 9 and 10, the collar mount plate 127 may include a protruding portion 130 which is adapted to receive the mounting end 139 of the support column 131. The mounting end 139 of the support column 131 is removably secured to the protrusion. In an exemplary embodiment, a screw-type fastener system 136 is utilized to secure the mounting end 139 of the support column 131 to the protruding portion.

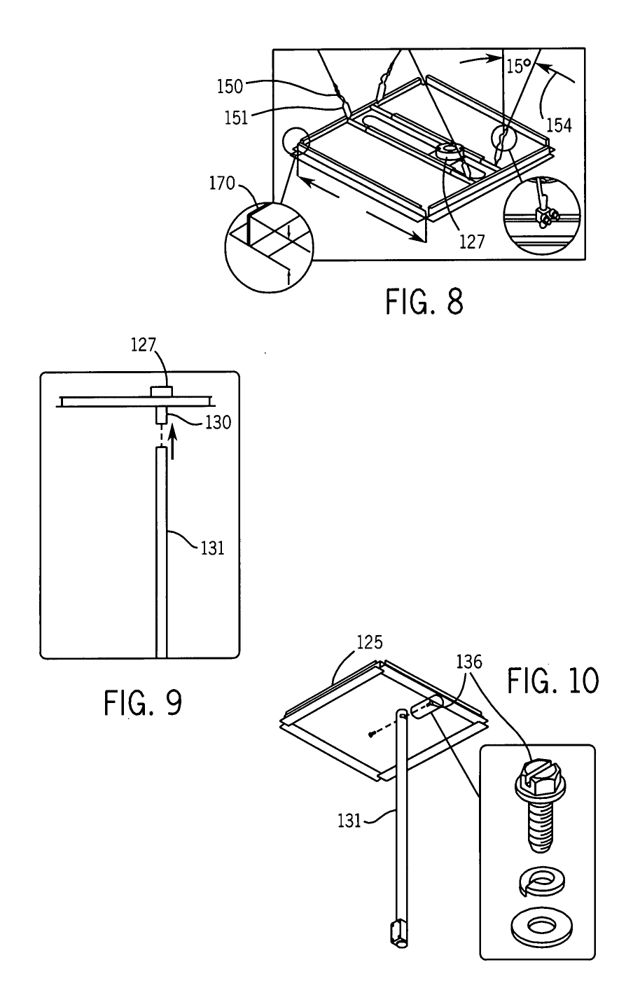

In one embodiment shown in FIG. 8, the display stand 110 is secured to the ceiling through the use of a suspension system 150. The suspension system 150 may comprise turnbuckles 151 which are affixable to the ceiling tray 125 and which are to cables 154. The cables 154 are engageable with the ceiling to anchor the display stand 110 therefrom. The ceiling tray 125 may be configured so as to blend in with a ceiling. For example, the ceiling tray 125 may include an edge 170 for engaging the ceiling, such that the ceiling tray 125 is adapted to replace a standard ceiling tile in a ceiling grid (not shown) with the edge 170 engaging the grid (not shown).

As shown in FIGS. 5A-D, one embodiment of the present invention comprises a video display stand 110 that is mountable for support either from above the video display stand 110 as a hanging display (e.g., a ceiling) or from below the video display stand 110 as a pedestal-type display (e.g., a floor). The video display 111 and adaptor assembly 112 are engagable with the support column 131, whether the support column 131 is mounted to the ceiling tray 125 or the base 123 as described above.

In an exemplary embodiment, as shown in FIG. 2, the support column 131 is extendable and the inner extension column 132 includes a mounting end 139 engagable with the base 123 and a second end 134 engageable with the outer extension column 135, the columns 132, 135 being slidably engagable with each other. The inner extension column 132 includes a first inner extension column end 133 and a second inner extension column end 134 engageable with the support column 131. In an exemplary embodiment of the present invention, the second inner extension column end 134 is adapted to fit within the outer extension column 135, with the inner extension column 132 being slidably positioned at least partially within the outer extension column 135 at a first end 137 and the support column 131 including a mechanism for securing 136 the inner extension column 132 to the outer extension column 135, such as but not limited to a bolt. The mounting assembly 121 may be removably fixable to the inner extension column 132 at the first inner extension column end 133 or to the outer extension column 135 at second outer extension column end 138.

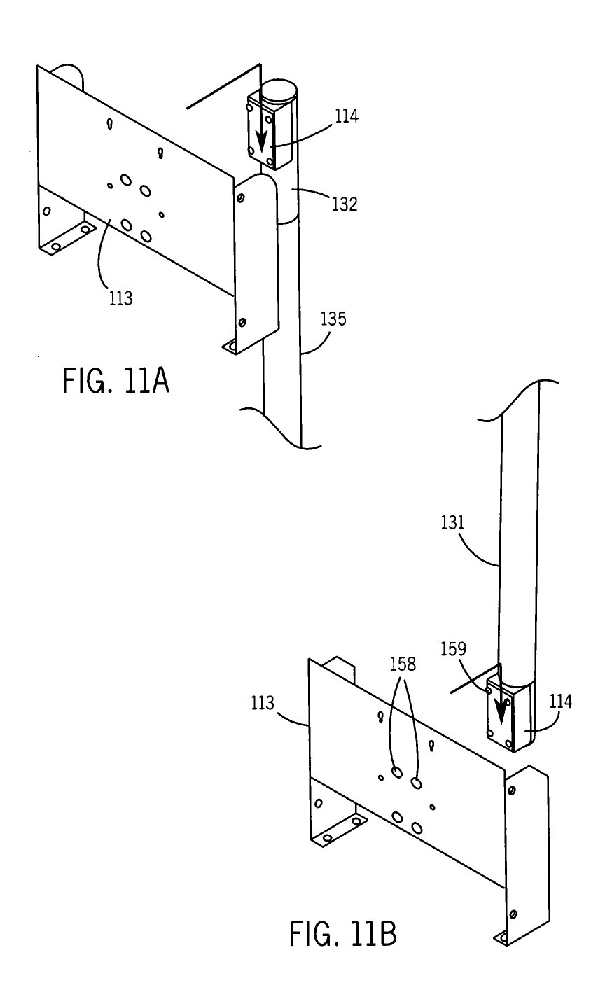

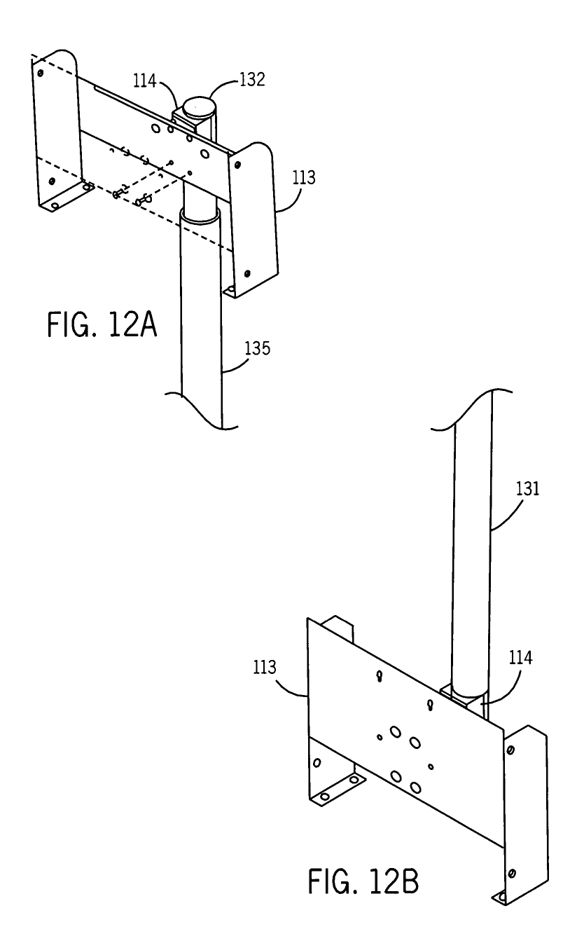

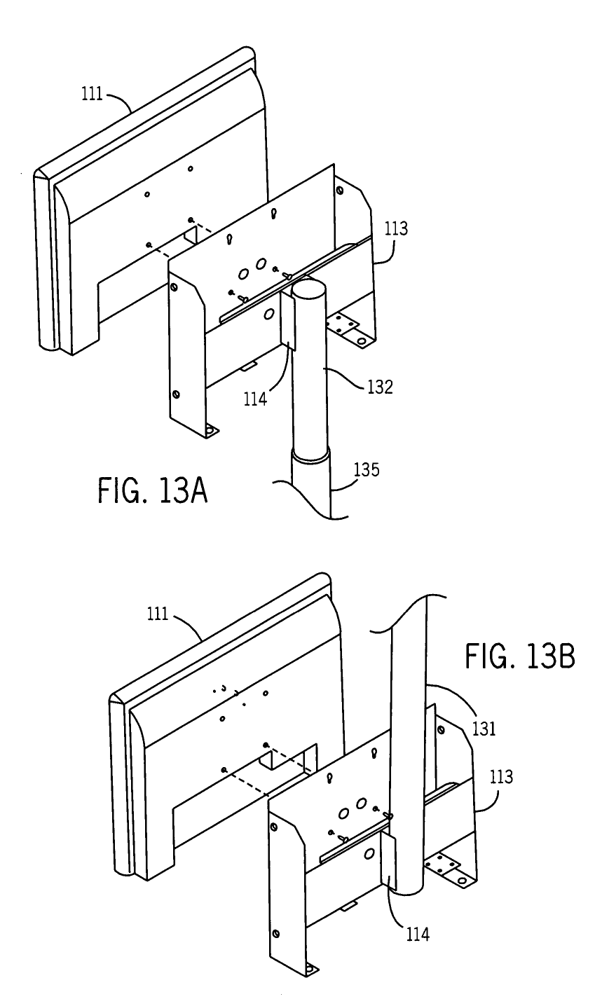

As illustrated in FIGS. 11A, 11B, 12A and 12B, the adaptor assembly 112 includes an adaptor plate 113. The adaptor plate 113 is removably affixable to the video display 111 and to the support column 131. The adaptor plate 113 affixes to the back of the video display 111 such that the display 111 is suspended from the adaptor plate 113 when the adaptor plate 113 is affixed to the support column 131. The adaptor plate 113 is engagable with the support column 131 for mounting to either a floor or a ceiling.

In one embodiment, shown in FIGS. 11A-B and 12A-B, the adaptor assembly 112 further comprises an adaptor bracket 114 affixed to the support column 131. The video display 110 is engagable with the adaptor plate 113 which is engagable with the adaptor bracket 114 that is positioned on the support column 131. As shown in FIGS. 11A-B and 12A-B the adaptor plate 113 is removably connectable with the adaptor bracket 114 prior to the attachment of the video display 111 to the adaptor plate 113. In an exemplary embodiment, the adaptor plate 113 includes one or more keyhole slots 158 that correspond to a protrusion 159 on the adaptor bracket 114.

The adaptor bracket 114 is affixed to the support column 131 at or proximate the second end 138 (i.e. substantially opposite the mounting end 139). In one exemplary embodiment, the adaptor bracket is affixed to first end 133 of the inner extension column 132. In another exemplary embodiment, the adaptor bracket 114 is affixed to the second end 138 of the outer extension column 135. The adaptor bracket may 114 may be affixed rigidly to the support column 131 at a single position, or the position of the adaptor bracket 114 on the support column 131 may be adjusted such as to adjust position of the video display 111 on the support column 131. The adaptor bracket 114 may be slidably positioned on the support column 131 in relation to the major axis of the support column 131 so as to allow for positioning of the adaptor bracket 114 along the length of the support column 131, such as using an adjustable retaining ring or a series of bolt holes and a retaining bolt. The adaptor bracket may be rotatable about the minor axis of the support column 131, so as to allow movement around the circumference of the support column 131. In still another embodiment, the adaptor bracket 114 is rotatable about the support column 131 to allow the video display 111 moved about the circumference of the support column 131.

In one exemplary embodiment shown in FIG. 17, an adapter plate cutout 115 is provided in the adaptor plate 113, and a support column cutout 116 is provided in support column 131 (and a cutout 119 in the adaptor bracket 114, if it is present) to allow for passage of wires from the video display 111 and other attached accessories 160 through the support column 131. In an exemplary embodiment, the support column 131 has a sufficient diameter to allow the necessary wires to pass there through from the video display 111 and/or accessories 160.

In one embodiment, shown in FIG. 15, a cover 117 is provided to engage the adaptor plate 113 encompassing the adaptor bracket 114 and at least a portion support column 131. The adaptor plate 113 may include a protrusion 171 which is engagable with a slot 172 in the cover 117 to allow for simple and removable connection of the cover 117 to the adaptor assembly 112.

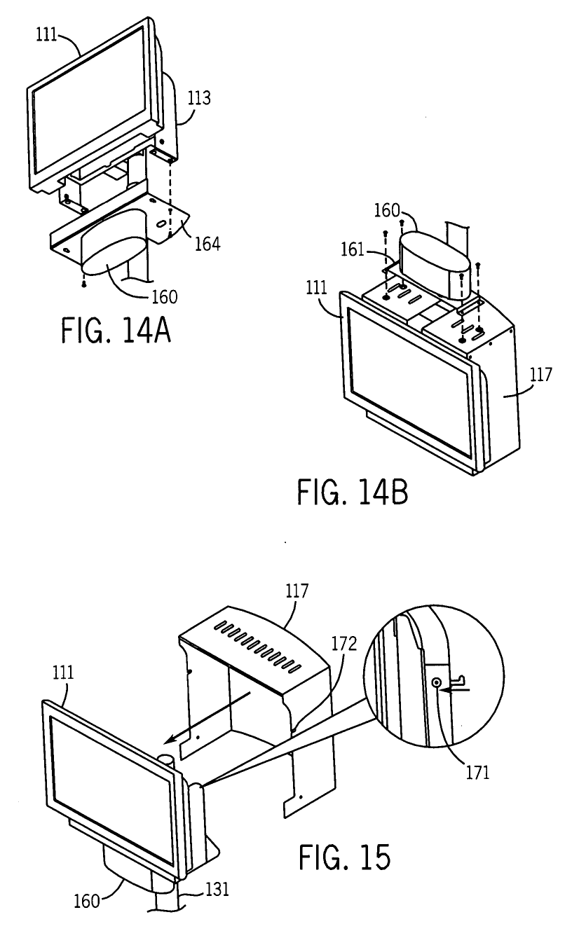

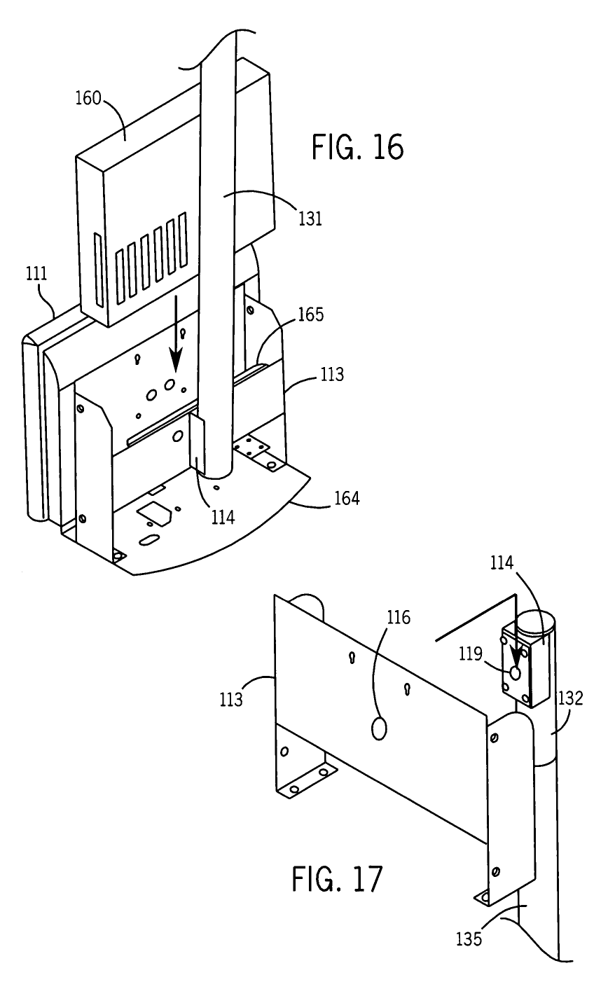

In one embodiment, the placement of accessories 160 is provided for. As illustrated in FIG. 14A, a bottom accessory mount 164 may be provided which is engagable with the bottom of the adaptor assembly 112 allowing the positioning of an accessory, such as a speaker, below the video display 111. As illustrated in FIG. 14B, a top accessory mount 161 may be provided which is positioned on top of the adaptor assembly 112 allowing the positioning of an accessory 160, such as a speaker, above the video display 111. As shown in FIG. 15, the adaptor assembly 112 may include a cavity 165 for the placement of accessories 160, such as but not limited to a television tuner, a video cassette recorder, a digital media player, or an optical media player.

The foregoing description of embodiments of the present invention have been presented for purposes of illustration and description. It is not intended to be exhaustive or to limit the present invention to the precise form disclosed, and modifications and variations are possible in light of the above teachings or may be acquired from practice of the present invention. The embodiments were chosen and described in order to explain the principles of the present invention and its practical application to enable one skilled in the art to utilize the present invention in various embodiments, and with various modifications, as are suited to the particular use contemplated.

What is claimed is:

1. A mount for displaying an electronic device, comprising:
a mounting assembly engagable with a plurality of surfaces;
a support column having a first end and a second end, the support column removably engagable with the mounting assembly at the first end; and
an adaptor assembly for operatively connecting the electronic device to the support column, the adaptor assembly including an adaptor bracket and an adaptor plate,
wherein the adaptor plate is configured for removable attachment to the electronic device and for operative connection to the support column via the adaptor bracket.

2. The mounting system of claim 1, wherein the mounting assembly comprises two mounts.

3. The mounting system of claim 1, wherein the two mounts comprise a ceiling mount for attachment of the system to an overhead surface and a floor mount for attachment of the system to a lower surface.

4. The mounting system of claim 1, further comprising an accessory adaptor removably affixed to the adaptor assembly.

5. The mounting system of claim 4, wherein the accessory adaptor and adaptor assembly define an accessory storage cavity.

6. The mounting system of claim 1, further comprising a cover removably affixed to the adaptor assembly, wherein the adaptor assembly and support column are at least partially disposed within the cover.

7. The mounting system of claim 1, wherein the support column is an extendable support column comprising an inner extension member and an outer extension member.

8. The mounting system of claim 1, wherein the mounting assembly comprises a tray connected with the overhead surface such that the support column extends downward from the tray.

9. The mounting system of claim 1, wherein the mounting assembly is a base attachable to a flooring surface such that the support column extends upward from the base.

10. The mounting system of claim 1, wherein the electronic device comprises a video display.

11. A mounting system for display of an audio/video device, comprising
a mounting tray configured to attach to a surface above the audio/video device;
a support column having a first end and a second end, the support column removably engagable with the mounting tray at the first end;
an adaptor assembly for operatively connecting the audio/video device to the support column, the adaptor assembly including an adaptor bracket and an adaptor plate,
wherein the adaptor plate is configured for removable attachment to the audio/video device and for operative connection to the support column via the adaptor bracket.

12. The mounting system of claim 11, wherein the mounting tray further comprises a carriage and a collar mount plate slidably affixed thereto, the first end of the support column removably engagable with the collar mount plate.

13. The mounting system of claim 12, wherein the mounting tray is suspended from the surface.

14. The mounting system of claim 11, wherein the adaptor assembly and the support column each includes a cutout portion to allow passage of wires from the audio/video device through the support column.

15. The mounting system of claim 11, wherein the support column is an extendable support column comprising an inner extension member and an outer extension member.

16. The mounting system of claim 11, further comprising a cover removably affixed to the adaptor assembly wherein the adaptor assembly and support column are at least partially disposed within the cover.

17. A mounting system for display of a video device comprising
a mounting assembly configured to attach to a surface below the video device;
a support column having a first end and a second end, the support column removably engagable with the mounting assembly at the first end;
an adaptor assembly for operatively connecting a video display to the support column, the adaptor assembly including an adaptor bracket and an adaptor plate;
wherein the adaptor plate is configured for removable attachment to the video device and for operative connection to the support column via the adaptor bracket.

18. The mounting system of claim 16, wherein the mounting assembly comprises a base, the base having a receptacle for receiving the first end of the support column.

19. The mounting system of claim 16, wherein the adaptor assembly and the support column each includes a cutout portion to allow passage of wires from the video device through the support column.

20. The mounting system of claim 16, wherein the support column is an extendable support column comprising an inner extension member and an outer extension member.

21. The mounting system of claim 16, further comprising a cover removably affixed to the adaptor assembly wherein the adaptor assembly and support column are at least partially disposed within the cover.

22. A mount for displaying an electronic device, comprising:
a mounting system for supporting the electronic device from a surface, the mounting system having a ceiling mount assembly and a floor mount assembly;
a support column having a first end and a second end, the support column removably engagable with either the ceiling mount assembly or floor mount assembly of the mounting system at the first end; and
an adaptor assembly for operatively connecting the electronic device to the support column, the adaptor assembly including an adaptor bracket and an adaptor plate,
wherein the adaptor plate is configured for removable attachment to the electronic device and for operative connection to the support column via the adaptor bracket.
